(19) United States
(12) Patent Application Publication
(10) Pub. No.: US 2024/0178039 A1
(43) Pub. Date: May 30, 2024

(54) ELECTROSTATIC CHUCK, ELECTROSTATIC CHUCK HEATER COMPRISING SAME, AND SEMICONDUCTOR HOLDING DEVICE

(71) Applicant: AMOSENSE CO.,LTD, Cheonan-si (KR)

(72) Inventors: Ji Hyung LEE, Cheonan-si (KR); Kyung Whan WOO, Cheonan-si (KR); Byoung Su JIN, Cheonan-si (KR); Young Jun AN, Cheonan-si (KR)

(73) Assignee: AMOSENSE CO.,LTD, Cheonan-si (KR)

(21) Appl. No.: 18/282,600

(22) PCT Filed: Mar. 18, 2022
(86) PCT No.: PCT/KR2022/003810

§ 371 Date: Sep. 18, 2023

(30) Foreign Application Priority Data
Mar. 19, 2021 (KR) 10-2021-0036005

(51) Int. Cl. H01L 21/683; C04B 35/591; C04B 37/02; H05B 3/28

(52) U.S. Cl. CPC H01L 21/6833; C04B 35/591; C04B 37/02; H05B 3/283; C04B 2235/3206; C04B 2235/3225; C04B 2235/3873; C04B 2235/428; C04B 2235/9607; C04B 2237/368; C04B 2237/68

(57) ABSTRACT

An electrostatic chuck is provided. An electrostatic chuck is implemented by comprising a silicon nitride sintered body and an electrostatic electrode embedded in the silicon nitride sintered body. Therefore, the electrostatic chuck includes a ceramic sintered body, which is silicon nitride, to have excellent plasma resistance, chemical resistance and thermal shock resistance while exhibiting heat dissipation performance of a level equivalent or similar to that of an aluminum nitride ceramic sintered body, which has been conventionally and widely used, and thus can be widely used in a semiconductor process.

### CROSS REFERENCE TO THE RELATED APPLICATIONS

This application is the national phase entry of International Application No. PCT/KR2022/003810, filed on Mar. 18, 2022, which is based upon and claims priority to Korean Patent Application No. 10-2021-0036005, filed on Mar. 19, 2021, the entire contents of which are incorporated herein by reference.

### TECHNICAL FIELD

The present invention relates to an electrostatic chuck, an electrostatic chuck heater including the same, and a semiconductor holding device.

### BACKGROUND

Electrostatic chucks are used to adsorb and hold semiconductor wafers in a series of steps such as film manufacturing processes such as semiconductor wafer transport, exposure, chemical vapor deposition (CVD), sputtering, etc., and microprocessing, cleaning, etching, and dicing. Research on dense ceramics as a substrate for such electrostatic chucks is being actively conducted. In particular, in equipment for semiconductor manufacturing, halogen corrosive gases such as CIF₃ are often used as etching gas or cleaning gas. In addition, in order to rapidly heat and cool a semiconductor wafer while inserting it into a chuck, the substrate of the electrostatic chuck is required to have high thermal conductivity. Furthermore, such high thermal shock resistance that is not easily destroyed by such rapid temperature changes is also required. Moreover, as plasma methods are used for etching and deposition in semiconductor processes, the demand for electrostatic chuck substrates with plasma resistance is increasing day by day.

However, aluminum nitride, which is widely used as a material for electrostatic chuck substrates, has excellent heat dissipation characteristics, but has the problem of being easily damaged by plasma during etching or deposition processes that use plasma during the semiconductor process, which reduces durability. In addition, there is a problem of frequent occurrence of cracks due to thermal shock. Moreover, there is a problem that durability reduction due to plasma or thermal shock shortens the replacement cycle of the electrostatic chuck.

### SUMMARY

### Technical Problem

The present invention has been devised in view of the above problems, and is directed to providing an electrostatic chuck with excellent heat dissipation characteristics while having chemical resistance to chemicals such as corrosive gases applied during the semiconductor process, plasma resistance to plasma processing, and thermal shock resistance due to rapid temperature changes, and an electrostatic chuck heater including the same, and a semiconductor holding device.

### Technical Solution

The present invention has been devised in view of the above problems, and provides an electrostatic chuck including a silicon nitride sintered body and an electrostatic electrode buried inside the silicon nitride sintered body.

According to an embodiment of the present invention, the silicon nitride sintered body may be formed by sintering silicon nitride powder containing 9% by weight or less of polycrystalline silicon.

In addition, the silicon nitride sintered body may be formed by sintering silicon nitride powder in which the weight ratio of the α crystal phase (ω(α+β)) is 0.7 or more in the total weight of the α crystal phase and the β crystal phase.

In addition, the silicon nitride sintered body may have a thermal conductivity of 70 W/mK or more and a three-point bending strength of 650 MPa or more.

In addition, the silicon nitride sintered body is manufactured by sintering silicon nitride power, and the silicon nitride powder is manufactured by processes including: manufacturing a mixed raw material powder containing a metallic silicon powder, and a crystal phase control powder containing a rare earth element-containing compound and a magnesium-containing compound; producing granules having a predetermined particle diameter by mixing the prepared mixed raw material powder with a solvent and an organic binder to form a slurry and then spray drying; nitriding the obtained granules at a predetermined temperature within the range of 1200 to 1500° C. while applying nitrogen gas at a predetermined pressure; and pulverizing the nitrided granules.

In addition, the metallic silicon powder may be dry-pulverized polycrystalline metallic silicon scrap or single crystal silicon wafer scrap to minimize contamination with metal impurities during pulverizing.

In addition, the metallic silicon powder may have an average particle diameter of 0.5 to 4 μm, the rare earth element-containing compound powder may have an average particle diameter of 0.1 to 1 μm, and the magnesium-containing compound powder may have an average particle diameter of 0.1 to 1 μm.

In addition, the granules may have a D50 value of 20 to 55 μm.

In addition, the rare earth element-containing compound may be yttrium oxide, the magnesium-containing compound may be magnesium oxide, and the mixed raw material powder may contain 2 to 5 mol % of yttrium oxide and 2 to 10 mol % of magnesium oxide.

In addition, during nitriding, the nitrogen gas may be applied at a pressure of 0.1 to 0.2 MPa.

In addition, during nitriding, the temperature may be heated from 1000° C. or higher to a predetermined temperature at a temperature increase rate of 0.5 to 10° C./min.

In addition, the present invention provides an electrostatic chuck heater having a first surface on which a wafer is adsorbed and a second surface opposing the first surface, the electrostatic chuck heater including: an electrostatic chuck unit comprising a first ceramic sintered body, which is the first surface, and an electrostatic electrode buried inside the first ceramic sintered body; and a heater unit comprising a second ceramic sintered body, which is the second surface, and at least one resistance heating element buried inside the second ceramic sintered body, wherein at least one of the first ceramic sintered body and the second ceramic sintered body is a silicon nitride sintered body formed by sintering silicon nitride powder.

According to an embodiment of the present invention, the first ceramic sintered body and the second ceramic sintered body may be simultaneously sintered and implemented as one body.

In addition, the present invention provides a semiconductor holding device, including the electrostatic chuck heater according to the present invention, and a cooling member disposed on the second surface of the electrostatic chuck heater.

### Advantageous Effects

The electrostatic chuck according to the present invention includes a ceramic sintered body, which is silicon nitride, to have excellent plasma resistance, chemical resistance and thermal shock resistance while exhibiting heat dissipation performance of a level equivalent or similar to that of an aluminum nitride ceramic sintered body, which has been conventionally and widely used, and thus can be widely used in a semiconductor process.

### BRIEF DESCRIPTION OF THE DRAWINGS

FIG. 1 is a cross-sectional mimetic diagram of an electrostatic chuck according to an exemplary embodiment of the present invention.

FIG. 2 is a cross-sectional mimetic diagram of an electrostatic chuck heater according to an exemplary embodiment of the present invention.

### DETAILED DESCRIPTION OF THE EMBODIMENTS

Hereinafter, exemplary embodiments of the present invention will be described in detail so that those of ordinary skill in the art can readily implement the present invention. The present invention may be embodied in many different forms and is not limited to the embodiments set forth herein.

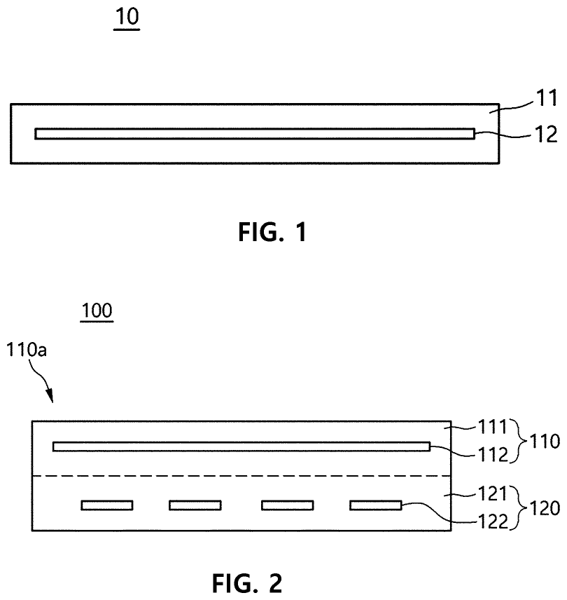

Referring to FIG. 1, an electrostatic chuck 10 according to an embodiment of the present invention is implemented including a silicon nitride sintered body 11 and an electrostatic electrode 12.

The electrostatic chuck 10 is a device that adsorbs and holds an object, for example, a semiconductor wafer, by electrostatic attraction, and for example, it is used to fix a semiconductor wafer in a semiconductor manufacturing process. The electrostatic chuck 10 may have a support surface that matches the shape of the object being gripped, and for example, the electrostatic chuck 10 may have a disk shape to match the shape of a wafer. In addition, the size of the electrostatic chuck 10 may be the size of an electrostatic chuck used in conventional semiconductor manufacturing, but is not limited thereto.

The silicon nitride sintered body 11 corresponds to the body of the electrostatic chuck 10, supports the electrostatic electrode 12 buried therein, and serves to provide a support surface for adsorbing adsorption objects such as semiconductor wafers. The silicon nitride sintered body 11 has excellent plasma resistance, chemical resistance, thermal shock resistance, and excellent heat dissipation characteristics, so it can be particularly useful in electrostatic chucks used in semiconductor processes.

According to an embodiment of the present invention, the silicon nitride sintered body 11 may be implemented using silicon nitride powder manufactured by a manufacturing method described later to exhibit improved properties in terms of the above-mentioned physical properties.

Specifically, the silicon nitride powder may be manufactured by processes including manufacturing a mixed raw material powder containing a metallic silicon powder, and a crystal phase control powder containing a rare earth element-containing compound and a magnesium-containing compound; producing granules having a predetermined particle diameter by mixing the mixed raw material powder with a solvent and an organic binder to form a slurry and then spray drying; nitriding the granules at a predetermined temperature within the range of 1200 to 1500° C. while applying nitrogen gas at a predetermined pressure; and pulverizing the nitrided granules.

First, the step of manufacturing a mixed raw material powder containing a metallic silicon powder, and a crystal phase control powder containing a rare earth element-containing compound and a magnesium-containing compound will be described.

The metallic silicon powder, which is the subject as the raw material powder, can be used without limitation in the case of metallic silicon powder that can produce silicon nitride powder through direct nitridation. As an example, the metallic silicon powder may be polycrystalline metallic silicon scrap or single crystal silicon wafer scrap. The polycrystalline metallic silicon scrap may be a by-product of polycrystalline metallic silicon used for manufacturing fixtures for semiconductor processing or solar panels, and the single crystal silicon wafer scrap is also a by-product of silicon wafer manufacturing, and thus, the manufacturing cost can be lowered by using these scraps, which are by-products, as raw material powder.

In addition, the polycrystalline metallic silicon scrap or single crystal silicon wafer scrap may have a purity of 99% or more, and may be more advantageous in ensuring the thermal conductivity and mechanical strength of the sintered body when sintering the silicon nitride powder manufactured therefrom.

In addition, the metallic silicon powder may have a resistivity of 1 to 100 Ωcm, which may be more advantageous for producing a silicon nitride powder having the desired physical properties of the present invention.

Meanwhile, the metallic silicon powder used as the raw material powder may preferably be obtained by pulverizing polycrystalline metallic silicon scrap (scrap) or single crystal silicon wafer scrap to a predetermined size. In this case, in order to prevent contaminants such as metal impurities due to pulverizing from being mixed into the raw material powder, the pulverizing may be done using a dry pulverizing method, and specifically, it can be powdered using a dry pulverizing method such as a disk mill, pin mill, or jet mill. If contaminants are contained in the metallic silicon powder, there is a risk of increased manufacturing time and cost as additional cleaning processes such as acid washing are required to remove contaminants. In this case, the average particle diameter of the pulverized metallic silicon powder may be 0.5 to 4 μm, more preferably 2 to 4 μm, and if the average particle diameter is less than 0.5 μm, it may be difficult to implement through dry pulverizing, there is a risk of increased possibility of contaminants mixed in due to fine powder, and densification may be difficult during sheet casting. In addition, if the average particle diameter of the metallic silicon powder exceeds 4 μm, nitridation is not easy, so there is a risk that unnitrided parts may exist, and densification of the final sintered body may be difficult.

Meanwhile, since silicon nitride is not easy to sinter due to reasons such as difficulty in self-diffusion and thermal decomposition at high temperatures, which limits the sintering temperature and it is difficult to produce a dense sintered body, and it may be difficult to control the crystal phase when producing silicon nitride powder using the direct nitriding method, in order to solve these difficulties and improve the physical properties of the substrate on which silicon nitride powder is sintered by removing impurities such as oxygen, a mixed raw material powder in which a crystal phase control powder is mixed with metallic silicon powder is used as a raw material powder. For example, for the crystal phase control powder, a compound containing a rare earth element-containing compound, an alkaline earth metal oxide, or a combination thereof may be used, and specifically, one or more selected from the group consisting of magnesium oxide (MgO), yttrium oxide (Y₂O₃), gadolinium oxide (Gd₂O), holmium oxide (HO₂O₃), erbium oxide (Er₂O₃), ytterbium oxide (Yb₂O₃), and dysprosium oxide (Dy₂O₃) may be used. However, the present invention essentially contains magnesium oxide and yttrium oxide in the crystal phase control powder in order to more easily control the crystal phase of the silicon nitride powder, and the magnesium oxide and yttrium oxide may implement a densified higher density sintered body when manufacturing the sintered body using the manufactured silicon nitride powder, and reduce the amount of residual grain boundary phase during sintering, thereby further improving the thermal conductivity of the sintered body.

For example, the mixed raw material powder may contain 2 to 5 mol % of yttrium oxide and 2 to 10 mol % of magnesium oxide. If the yttrium oxide is less than 2 mol %, it may be difficult to create a densified sintered body when sintering the implemented silicon nitride powder, and it may be difficult to capture oxygen on the grain boundary, and thus the amount of solid oxygen increases, leading to low thermal conductivity of the sintered body, and mechanical strength may be lowered. In addition, if the yttrium oxide exceeds 5 mol %, the grain boundary phase increases, and there is a risk that the thermal conductivity of the sintered body obtained by sintering the implemented silicon nitride powder is reduced and the fracture toughness is reduced. In addition, if the magnesium oxide is less than 2 mol %, both the thermal conductivity and mechanical strength of the sintered body obtained by sintering the implemented silicon nitride powder may be low, there is a risk of silicon being eluted during nitriding, and it may be difficult to manufacture a densified sintered body. In addition, if the magnesium oxide exceeds 10 mol %, the amount of magnesium remaining at the grain boundaries increases during sintering, and as a result, the thermal conductivity of the sintered body may be lowered, sintering of silicon nitride powder may not be easy, and fracture toughness may be reduced.

In addition, the rare earth element-containing compound powder may have an average particle diameter of 0.1 to 1 μm, and the magnesium-containing compound powder may have an average particle diameter of 0.1 to 1 μm, which may be more advantageous in achieving the purpose of the present invention.

Next, the step of producing granules having a predetermined particle diameter by mixing the prepared mixed raw material powder with a solvent and an organic binder to form a slurry and then spray drying is performed.

Instead of directly nitriding the mixed raw material powder, it is manufactured into granules with a predetermined particle diameter, and then a nitriding process described later is performed on the granules, and through this, the crystal phase of the silicon nitride powder produced can be more easily controlled by increasing the mixing uniformity of the mixed raw material powder, and a secondary phase of SizY₂O₃ can be formed, making it possible to manufacture silicon nitride powder with uniform characteristics that can improve uniformity while further improving the thermal conductivity and mechanical strength of the sintered body.

The granules may have a D50 value of 100 μm or less, more preferably 20 to 100 μm, even more preferably 20 to 55 μm, more preferably 20 to 40 μm, and if D50 exceeds 100 μm, nitrogen gas cannot flow smoothly into the granule, so nitridation does not occur completely, and silicon that has not been nitrided may melt and elute out of the granule, and if such silicon nitride powder is manufactured into a sintered body, there is a concern that the silicon eluted during the production of the silicon nitride powder may be eluted out again during the sintering process of the sintered body. Here, the D50 value means a value based on 50% volume measured using a laser diffraction scattering method.

Meanwhile, the granules can be obtained through a dry spray method, and can be obtained using known conditions and devices that can perform the dry spray method, so the present invention is not particularly limited thereto. In addition, the mixed raw material powder is implemented as a slurry mixed with a solvent and an organic binder and then sprayed dry, and the solvent and organic binder used during slurring to form ceramic powder into granules can be used without limitation. For example, the solvent preferably includes one or more selected from ethanol, methanol, isopropanol, distilled water, and acetone. In addition, it is preferable to use a polyvinyl butyral (PVB)-based binder as the organic binder. Meanwhile, when manufacturing granules, an organic binder is contained, but if it is contained in a trace amount, a separate degreasing process may not be performed before the nitriding process described later.

Next, the step of nitriding the obtained granules at a predetermined temperature within the range of 1200 to 1500° C. while applying nitrogen gas at a predetermined pressure is performed.

In this case, during nitriding treatment, the nitrogen gas may be applied at a pressure of 0.1 to 0.2 MPa, and more preferably at a pressure of 0.15 to 0.17 MPa. If the nitrogen gas pressure is less than 0.1 MPa, nitridation may not occur completely. In addition, when the nitrogen gas pressure exceeds 0.2 MPa, silicon elution occurs during the nitriding process. In addition, during nitriding treatment, it can be heated at a temperature increase rate of 0.5 to 10° C./min from 1000° C. or higher to a predetermined temperature, but if the temperature increase rate from 1000° C. or higher to the predetermined temperature is less than 0.5° C./min, the sintering time may be excessively extended. In addition, when the temperature increase rate exceeds 10° C./min, silicon is eluted, making it difficult to manufacture powder completely nitrided with silicon nitride.

In addition, the temperature during nitriding treatment may be selected within the range of 1200 to 1500° C., but if the temperature during nitriding treatment is less than 1200° C., nitriding may not occur uniformly. In addition, when the temperature during nitriding treatment exceeds 1500° C., the β crystal phase is rapidly formed, so densification may be difficult when manufacturing a sintered body using such silicon nitride powder.

Next, the step of pulverizing the nitrided granules is performed.

This is a step of manufacturing nitrided granules into silicon nitride powder, and can preferably be performed by a dry method to prevent mixing of contaminants during pulverizing, for example, by using an air jet mill.

The silicon nitride powder manufactured by the above-described manufacturing method contains 9% by weight or less of polycrystalline silicon derived from molten silicon, and such silicon nitride powder may be suitable for manufacturing a sintered body with improved mechanical strength and thermal conductivity. The silicon nitride powder may contain preferably 8% by weight or less of polycrystalline silicon derived from molten silicon, more preferably 6% by weight or less, more preferably 4% by weight or less, and even more preferably 0% by weight.

According to an embodiment of the present invention, the weight ratio of the α crystal phase in the total weight of the α crystal phase and the β crystal phase may be 0.7 or more, but if the weight ratio of the α crystal phase in the total weight of the α crystal phase and the β crystal phase is less than 0.7, it may be difficult to increase the density of the sintered body using silicon nitride powder, and it may be difficult to improve thermal conductivity and mechanical strength, and especially may be difficult to improve mechanical strength.

In addition, the silicon nitride powder can more uniformly form a secondary phase of Si₂Y₂O₃ on the grain boundaries of the sintered body implemented through this, and through this, it can exhibit an enhanced effect in improving the thermal conductivity of the sintered body.

In addition, the silicon nitride powder may have an average particle diameter of 2 to 5 μm, which may be more advantageous for implementing a sintered body with improved mechanical strength and thermal conductivity. In addition, as an example, D90 may be 7.5 μm or less, and D10 may be 2.5 μm or more, which may be advantageous for achieving the purpose of the present invention.

The above-described silicon nitride powder can be manufactured into a molded body of a desired shape, for example, a disk shape, and then implemented into a silicon nitride sintered body 11 through a sintering process. The molded body can be manufactured using a known sheet lamination method or press molding method.

Describing the molded body manufacturing method according to the sheet lamination method, it can be manufactured by mixing the above-described silicon nitride powder with a solvent and an organic binder and molding the resulting slurry into a sheet according to a known method such as the doctor blade method. Afterwards, a molded body can be manufactured by stacking and heat-compressing several manufactured ceramic green sheets and processing them to a specified size.

In this case, as a solvent provided in the slurry, an organic solvent can be used to dissolve the organic binder and disperse the silicon nitride powder to adjust the viscosity, and as the organic solvent, any substance that can dissolve the organic binder can be used without limitation, for example, terpineol, dihydro terpineol (DHT), dihydro terpineol acetate (DHTA), butyl carbitol acetate (BCA), ethylene glycol, ethylene, isobutyl alcohol, methyl ethyl ketone, butyl carbitol, texanol (2,2,4-trimethyl-1,3-pentanediol monoisobutyrate), ethylbenzene, isopropylbenzene, cyclohexanone, cyclopentanone, dimethyl sulfoxide, diethyl phthalate, toluene, mixtures thereof, etc. can be used. At this time, it is preferable to mix 50 to 100 parts by weight of the solvent with respect to 100 parts by weight of silicon nitride powder. If the solvent content is less than 50 parts by weight, the viscosity of the slurry is high, making it difficult to perform tape casting and it may be difficult to control the coating thickness, and if the solvent content exceeds 100 parts by weight, the viscosity of the slurry becomes too diluted, so it takes a long time to dry, and it may be difficult to control the thickness.

In addition, it is preferable to mix 5 to 20 parts by weight of the organic binder with respect to 100 parts by weight of silicon nitride powder. The organic binder may be a cellulose derivative such as ethyl cellulose, methyl cellulose, nitrocellulose, or carboxycellulose, or a polymer resin such as polyvinyl alcohol, acrylic acid ester, methacrylic acid ester, or polyvinyl butyral, and considering forming a sheet-shaped molded body by a tape casting method, polyvinyl butyral can be used as the organic binder.

Meanwhile, the slurry may further include known substances contained in slurries for forming sheets, such as dispersants and plasticizers, and the present invention is not particularly limited thereto.

Meanwhile, one green sheet for manufacturing a molded body may be treated with electrode ink for forming the electrostatic electrode 12 so that the electrostatic electrode 12, which will be described later, is buried inside the silicon nitride sintered body 11. The electrode ink may be a mixture of a conductive component, a solvent, a binder, etc., but the present invention is not particularly limited thereto.

The implemented molded body may be sintered through a known method to form a silicon nitride sintered body 11, and in the sintering process, the electrode ink provided inside may also be sintered to form the electrostatic electrode 12, thereby manufacturing the electrostatic chuck 10 to be finally obtained. Specifically, the molded body may be sintered at a temperature of 1800 to 1900° C. at 0.5 to 1.0 MPa, which can be more advantageous in implementing a high-quality silicon nitride sintered body. In addition, the silicon nitride sintered body 11 implemented as a result of this may, for example, have a thermal conductivity of 70 W/mK or more, preferably 80 W/mK or more, more preferably 90 W/mK or more, and have a three-point bending strength of 650 MPa or more, preferably 680 MPa or more, more preferably 700 MPa or more. In addition, since the uniformity of the silicon nitride sintered body is excellent, the standard deviation of the thermal conductivity measured for each of the silicon nitride sintered bodies after dividing the sintered bodies into 10 equal parts may be 5 W/mK or less, more preferably 3 W/mK or less, and the standard deviation of the three-point bending strength may be 25 MPa or less, more preferably 20 MPa or less. In addition, the silicon nitride sintered body may have a sintered density of 3.0 g/al or more, and more preferably 3.2 g/ail or more.

Next, the electrostatic electrode 12 buried inside the silicon nitride sintered body 11 mentioned above will be described.

The electrostatic electrode 12 plays the role of holding the semiconductor wafer on the silicon nitride sintered body 11 by generating electrostatic force between the adsorption object, for example, a semiconductor wafer, and the silicon nitride sintered body 11. The electrostatic force may be of the Coulomb or Johnson-Rahbek type.

The electrostatic electrode 12 may be made of the material of an electrostatic electrode provided in a typical electrostatic chuck, and may be formed of a conductive component such as tungsten or molybdenum, for example. In addition, the electrostatic electrode 12 may be provided as one surface electrode or a pair of internal electrodes, but is not limited thereto, and may be buried in the silicon nitride sintered body 11 in the same number, shape, and size as the electrostatic electrodes provided in a typical electrostatic chuck.

The present invention includes an electrostatic chuck heater implemented using the electrostatic chuck described above. Describing this with reference to FIG. 2, the electrostatic chuck heater 100 is implemented by including an electrostatic chuck unit 110 that adsorbs and fixes an adsorption object using electrostatic force, and a heater unit 120 that has a function of generating heat to be provided to the adsorption object. In addition, the electrostatic chuck heater 100 has a first surface on which an adsorption object, for example a semiconductor wafer, is adsorbed, and a second surface opposing this, and the electrostatic chuck unit 110 and the heater unit 120 are positioned so that the first surface becomes a surface of the electrostatic chuck unit 110 and the second surface becomes a surface of the heater unit 120.

The electrostatic chuck unit 110 includes a first ceramic sintered body 111 and an electrostatic electrode 112 buried inside the first ceramic sintered body 111, and the heater unit 120 includes a second ceramic sintered body 121 and at least one resistance heating element 122 buried inside the second ceramic sintered body 121. In this case, at least one of the first ceramic sintered body 111 and the second ceramic sintered body 121 is provided as a silicon nitride sintered body formed by sintering silicon nitride powder, and may preferably be the silicon nitride sintered body 11 of the electrostatic chuck 10 described above.

In addition, preferably, both the first ceramic sintered body 111 and the second ceramic sintered body 121 may be silicon nitride sintered bodies. Meanwhile, if only one of the first ceramic sintered body 111 and the second ceramic sintered body 121 is a silicon nitride sintered body, the other may be a ceramic sintered body employed in a typical electrostatic chuck heater, and the present invention is not particularly limited thereto.

In addition, the first ceramic sintered body 111 and the second ceramic sintered body 121 may be simultaneously sintered and implemented as one body. That is, the first ceramic sintered body 111 and the second ceramic sintered body 121 may be manufactured by manufacturing ceramic components into green sheets and stacking them as described in the manufacturing method of the silicon nitride sintered body 11 described above, and in a state where the green sheets forming the first ceramic sintered body 111 and the green sheets forming the second ceramic sintered body 121 are stacked, they may be manufactured as one molded body, and simultaneously sintered to implement a ceramic sintered body integrated into one body. However, it is not limited thereto, and it should be noted that the first ceramic sintered body 111 and the second ceramic sintered body 121 may be manufactured independently and then attached using a known adhesive method to be integrated.

Meanwhile, between the first ceramic sintered body 111 and the second ceramic sintered body 121, a separate intermediate layer (not shown) having a different composition from the first ceramic sintered body 111 and the second ceramic sintered body 121 may be further included, through which leakage of current transmitted from one of the electrostatic electrode 112 and the resistance heating element 122 to the other can be prevented. Alternatively, when the first ceramic sintered body 111 and the second ceramic sintered body 121 have different compositions, it is possible to prevent any component from diffusing from one sintered body to the other sintered body.

In addition, the electrostatic chuck unit 110 includes an electrostatic electrode 112, and the electrostatic electrode 112 may be an electrostatic electrode made of a material provided in a typical electrostatic chuck, for example, molybdenum or tungsten.

In addition, the heater unit 120 is provided with a resistance heating element 122 inside the second ceramic sintered body 121, and the resistance heating element 122 may be any one used as a heating element in a typical electrostatic chuck heater without limitation, and may be formed of a conductive material such as tungsten or molybdenum. In this case, as shown in FIG. 2, several resistance heating elements 122 may be buried inside the second ceramic sintered body 121, or a single resistance heating element 122 may be provided in various shapes such as a spiral shape. Meanwhile, the specific pattern in which the resistance heating element 122 is buried can be adopted without limitation as the pattern of the resistance heating element in a typical electrostatic chuck heater, so the present invention is not particularly limited thereto.

In addition, the present invention includes a semiconductor holding device including the electrostatic chuck heater 100 according to the present invention described above and a cooling member disposed on the second surface of the electrostatic chuck heater 100.

The cooling member is used to control the temperature of the semiconductor wafer held on the electrostatic chuck heater 100 and may serve to cool the semiconductor wafer heated through the heater unit 120. The cooling member may be used without limitation in the case of a cooling member commonly employed in a semiconductor holding device. For example, the cooling member may include a cooling substrate made of aluminum or titanium and a flow path through which coolant can flow inside the cooling substrate.

In addition, the semiconductor holding device may employ a known configuration for the semiconductor holding device in addition to the electrostatic chuck heater 100 and the cooling member, for example, a power source capable of applying current to the electrostatic electrode 112 and the resistance heating element 122 of the electrostatic chuck heater 100, a focus ring placement table including a focus ring electrostatic chuck, and an installation plate supporting them, without limitation, and the present invention is not particularly limited thereto.

### MODE FOR CARRYING OUT THE INVENTION

The present invention will be described in more detail through the following examples, but the following examples are not intended to limit the scope of the present invention, which should be construed to aid understanding of the present invention.

In order to examine the characteristics of the silicon nitride sintered body provided in the electrostatic chuck or electrostatic chuck heater, the silicon nitride sintered body was manufactured through the preparation example below.

### Preparation Example 1

Polycrystalline silicon scrap (purity 99.99%, resistivity 102 cm) derived from a fixture for semiconductor processing was dry-pulverized using a jet mill to prepare metallic silicon powder with an average particle diameter of 4 μm. By mixing this with 2 mol % yttrium oxide with an average particle diameter of 0.5 μm and 5 mol % magnesium oxide with an average particle diameter of 0.5 μm, mixed raw material powder was prepared. 100 parts by weight of the prepared mixed raw material powder was mixed with 80 parts by weight of ethanol as a solvent and 10 parts by weight of polyvinyl butyral as an organic binder to prepare a slurry for granule production, which was spray-dried using a thermal spray device to produce granules with a D50 value of 20 μm. The manufactured granules were heat treated at a nitrogen gas pressure of 0.15 MPa in which specifically, the temperature increase rate was set at 5° C./min up to 1000° C. and 0.5° C./min from 1000° C. to 1400° C., and then heat treated at 1400° C. for 2 hours to obtain nitrided granules, and then this was pulverized through an air jet mill to obtain silicon nitride powder with an average particle diameter of 2 μm as shown in Table 1 below.

Afterwards, 5 parts by weight of polyvinyl butyral resin and 50 parts by weight of a 5:5 solvent mixture of toluene and ethanol as a solvent were mixed, dissolved, and dispersed in a ball mill based on 100 parts by weight of the obtained silicon nitride powder. Afterwards, the prepared slurry was produced into a sheet shape through a typical tape casting method, then produced into a 170 μm sheet shape, then four prepared sheets were cross-laminated and heat-treated at 1900° C. 4 hours under a nitrogen atmosphere to produce a silicon nitride sintered body as shown in Table 1.

### Preparation Example

It was manufactured in the same manner as Preparation Example 1, but instead of implementing the mixed raw material powder into granules, silicon nitride powder was obtained, and a silicon nitride sintered body as shown in Table 1 below was manufactured.

### Experimental Example 1

The following physical properties were evaluated for the silicon nitride powder or silicon nitride ceramic sintered body prepared in Preparation Example 1 and Comparative Preparation Example, and the results are shown in Table 1 below.

### 1. D50

The 50% volume reference value measured using the laser diffraction scattering method was taken as the D50 value.

### 2. Sintered Density

The sintered density of the manufactured silicon nitride sintered body was measured using the Archimedes method.

### 3. Thermal Conductivity and Uniformity

After preparing the manufactured silicon nitride ceramic sintered body into a total of 10 specimens for Preparation Example 1 and Comparative Preparation Example, thermal conductivity was measured using the KS L 1604 (ISO 18755, ASTM E 1461) method, and the average value and standard deviation of the measured values were measured, and it means that the closer the standard deviation is to 0, the more uniform the thermal conductivity is.

### 4. Three-Point Bending Strength and Uniformity

After preparing the manufactured silicon nitride sintered body into a total of 10 specimens for Preparation Example 1 and Comparative Preparation Example, the three-point bending strength (S) was measured using the KS L 1590 (ISO 14704) method and then substituted into the equation below to calculate the average value and standard deviation of the calculated values. It means that the closer the three-point bending strength standard deviation is to 0, the more uniform the three-point bending strength is.

S=3PL/(2bd²) [Equation]

In the equation, P is the failure load, L is the distance between points, b is the width of the beam, and d is the thickness of the beam.

TABLE 1

| | | | | Comparative |
|---|---|---|---|---|
| | | | Example 1 | Example 1 |
| Mixed raw | MgO (mol %) | | 5 | 5 |
| material | Y₂O₃ (mol %) | | 2 | 2 |
| powder | | | | |
| Granule D50 (μm) | | | 20 | — |
| Nitriding | Nitrogen gas pressure (MPa) | | 0.15 | 0.15 |
| conditions | Temperature increase rate from | | 0.5 | 0.5 |
| | 1000° C. to nitriding temperature | | | |
| | (° C./min) | | | |
| | Nitriding temperature (° C.) | | 1400 | 1400 |
| Silicon | Sintered density (g/cm³) | | 3.21 | 3.21 |
| nitride | Thermal | Average value | 94 | 81 |
| sintered | conductivity | Standard | 3 | 8 |
| body | (W/mK) | deviation | | |
| | Three-point | Average value | 680 | 550 |
| | bending | Standard | 20 | 50 |
| | strength (MPa) | deviation | | |

As can be seen from Table 1, the silicon nitride sintered body according to Preparation Example 1 has excellent thermal conductivity and three-point bending strength and exhibits uniform characteristics compared to the silicon nitride sintered body according to Comparative Preparation Example, which is expected to be a result of the granulation of the silicon nitride powder used to manufacture the silicon nitride sintered body and the resulting increase in nitriding uniformity.

### Preparation Examples 2 to 9

It was manufactured in the same manner as Preparation Example 1, but silicon nitride powder was obtained by changing the content of ingredients, D50 value of granules, nitriding conditions, etc. in the mixed raw material powder as shown in Table 2 or Table 3 below, and through this, silicon nitride powder and silicon nitride sintered body as shown in Table 2 or Table 3 below were manufactured.

### Experimental Example 2

The following physical properties were evaluated for the silicon nitride powder or silicon nitride sintered body prepared in Preparation Examples 1 to 9, and the results are shown in Table 2 or Table 3 below.

### 1. Crystal Phase

For silicon nitride powder, the α and β crystal phases were quantified through XRD measurement, and the weight ratio of the α crystal phase was calculated using the equation below.

Weight ratio of a crystal phase=ω(α+β)

### 2. D50

The 50% volume reference value measured using the laser diffraction scattering method was taken as the D50 value.

### 3. Sintered Density

The sintered density of the manufactured silicon nitride sintered body was measured using the Archimedes method.

### 4. Thermal Conductivity

The thermal conductivity of 10 silicon nitride sintered bodies manufactured for each example was measured using the KS L 1604 (ISO 18755, ASTM E 1461) method, and the average value of the measured values was calculated.

### 5. Three-Point Bending Strength

For 10 silicon nitride sintered bodies manufactured in each example, the three-point bending strength (S) was measured using the KS L 1590 (ISO 14704) method and calculated using the equation below, and the average value of the calculated values was calculated.

S=3PL/(2bd²) [Equation]

In the equation, P is the failure load, L is the distance between points, b is the width of the beam, and d is the thickness of the beam.

TABLE 2

| | | Preparation | Preparation | Preparation | Preparation | Preparation | Preparation |
|---|---|---|---|---|---|---|---|
| | | Example 1 | Example 2 | Example 3 | Example 4 | Example 5 | Example 6 |
| Mixed raw | MgO (mol %) | 5 | 5 | 5 | 5 | 5 | 5 |
| material | Y₂O₃ (mol %) | 2 | 2 | 2 | 2 | 2 | 2 |
| powder | | | | | | | |
| Granule D50 (μm) | | 20 | 30 | 40 | 60 | 80 | 100 |
| Nitriding | Nitrogen gas pressure | 0.15 | 0.15 | 0.15 | 0.15 | 0.15 | 0.15 |
| conditions | (MPa) | | | | | | |
| | Temperature increase rate | 0.5 | 0.5 | 0.5 | 0.5 | 0.5 | 0.5 |
| | from 1000° C. to nitriding | | | | | | |
| | temperature (° C./min) | | | | | | |
| | Nitriding temperature (° C.) | 1400 | 1400 | 1400 | 1400 | 1400 | 1400 |
| Silicon | α crystal phase | 0.97 | 0.92 | 0.87 | 0.85 | 0.78 | 0.70 |
| nitride | weight ratio | | | | | | |
| power | [α/(α + β)] | | | | | | |
| | Eluted Si (% by weight) | 0 | 0 | 0 | 4 | 8 | 9 |
| Silicon | Sintered density (g/cm³) | 3.21 | 3.20 | 3.17 | 3.01 | 2.92 | 2.94 |
| nitride | Thermal conductivity | 94 | 82 | 77 | 62 | 58 | 53 |
| sintered | (W/mK) | | | | | | |
| body | Three-point bending | 680 | 750 | 650 | 460 | 420 | 380 |
| | strength (MPa) | | | | | | |

TABLE 3

| | | Preparation | Preparation | Preparation |
|---|---|---|---|---|
| | | Example 7 | Example 8 | Example 9 |
| Mixed raw material powder | MgO (mol %) | 7 | 10 | 15 |
| Mixed raw material powder | Y₂O₃ (mol %) | 2 | 2 | 2 |
| Granule D50 (μm) | | 32 | 32 | 32 |
| Nitriding conditions | Nitrogen gas pressure (MPa) | 0.15 | 0.15 | 0.15 |
| Nitriding conditions | Temperature increase rate from 1000° | 0.5 | 10.5 | 10.5 |
| | C. to nitriding temperature (° C./min) | | | |
| Nitriding conditions | Nitriding temperature (° C.) | 1400 | 1400 | 1400 |
| Silicon nitride power | α crystal phase weight ratio [α/(α + β)] | 0.79 | 0.92 | 0.95 |
| Silicon nitride power | Eluted Si (% by weight) | 0 | 0 | 0 |
| Silicon nitride sintered body | Sintered density (g/cm³) | 3.21 | 3.21 | 3.20 |
| Silicon nitride substrate | Thermal conductivity (W/mK) | 121 | 87 | 82 |
| Silicon nitride substrate | Three-point bending strength (MPa) | 750 | 720 | 680 |

As can be seen through Table 2 and Table 3,

It can be confirmed that the preparation examples are very suitable powders for improving the thermal conductivity and three-point bending strength of a substrate manufactured using the silicon nitride powder obtained by manufacturing the mixed raw material powder into granules of an appropriate size and then nitriding them. However, when the size of the granule is large, as in Preparation Example 6, the content of silicon eluted from the silicon nitride powder may be high, and in this case, it can be seen that it may be insufficient to improve the mechanical strength and thermal conductivity of the manufactured silicon nitride sintered body.

Although exemplary embodiments of the present invention have been described above, the idea of the present invention is not limited to the embodiments set forth herein. Those of ordinary skill in the art who understand the idea of the present invention may easily propose other embodiments through supplement, change, removal, addition, etc. of elements within the scope of the same idea, but the embodiments will be also within the idea scope of the present invention.

What is claimed is:

1. An electrostatic chuck, comprising:
a silicon nitride sintered body formed by sintering silicon nitride powder; and
an electrostatic electrode buried inside the silicon nitride sintered body.

2. The electrostatic chuck of claim 1, wherein
the silicon nitride sintered body contains 9% by weight or less of polycrystalline silicon.

3. The electrostatic chuck of claim 1, wherein
the silicon nitride sintered body is formed by sintering silicon nitride powder in which a weight ratio of an α crystal phase is 0.7 or more in a total weight of the α crystal phase and a β crystal phase.

4. The electrostatic chuck of claim 1, wherein
the silicon nitride sintered body has a thermal conductivity of 70 W/mK or more and a three-point bending strength of 650 MPa or more.

5. The electrostatic chuck of claim 1, wherein
the silicon nitride powder is manufactured by processes comprising:
manufacturing a mixed raw material powder containing a metallic silicon powder, and a crystal phase control powder containing a rare earth element-containing compound and a magnesium-containing compound;
producing granules having a predetermined particle diameter by mixing the prepared mixed raw material powder with a solvent and an organic binder to form a slurry and then spray drying;
nitriding the granules at a predetermined temperature within a range of 1200° C. to 1500° C. while applying nitrogen gas at a predetermined pressure, to obtain nitrided granules; and
pulverizing the nitrided granules.

6. The electrostatic chuck of claim 5, wherein
the metallic silicon powder is dry-pulverized polycrystalline metallic silicon scrap or single crystal silicon wafer scrap to minimize contamination with metal impurities during pulverizing.

7. The electrostatic chuck of claim 5, wherein
the metallic silicon powder has an average particle diameter of 0.5 μm to 4 μm, rare earth element-containing compound powder has an average particle diameter of 0.1 μm to 1 μm, and magnesium-containing compound powder has an average particle diameter of 0.1 μm to 1 μm.

8. The electrostatic chuck of claim 5, wherein
the granules have a D50 value of 20 μm to 55 μm.

9. The electrostatic chuck of claim 5, wherein
the rare earth element-containing compound is yttrium oxide, and the magnesium-containing compound is magnesium oxide, and
the mixed raw material powder contains 2 mol % to 5 mol % of yttrium oxide and 2 mol % to 10 mol % of magnesium oxide.

10. The electrostatic chuck of claim 5, wherein
during nitriding, a temperature is heated from 1000° C. or higher to the predetermined temperature at a temperature increase rate of 0.5° C./min to 10° C./min, and the nitrogen gas is applied at a pressure of 0.1 MPa to 0.2 MPa.

11. An electrostatic chuck heater having a first surface on which a wafer is adsorbed and a second surface opposing the first surface, the electrostatic chuck heater comprising:
an electrostatic chuck unit comprising a first ceramic sintered body and an electrostatic electrode buried inside the first ceramic sintered body, wherein the first ceramic sintered body is the first surface, and
a heater unit comprising a second ceramic sintered body, and at least one resistance heating element buried inside the second ceramic sintered body, wherein the second ceramic sintered body is the second surface;
wherein at least one of the first ceramic sintered body and the second ceramic sintered body is a silicon nitride sintered body formed by sintering silicon nitride powder.

12. The electrostatic chuck heater of claim 11, wherein the first ceramic sintered body and the second ceramic sintered body are simultaneously sintered and implemented as one body.

13. A semiconductor holding device, comprising:
the electrostatic chuck heater according to claim 11; and
a cooling member disposed on the second surface of the electrostatic chuck heater.

14. The electrostatic chuck heater of claim 11, wherein the silicon nitride sintered body contains 9% by weight or less of polycrystalline silicon.

15. The electrostatic chuck heater of claim 11, wherein the silicon nitride sintered body is formed by sintering silicon nitride powder in which a weight ratio of an α crystal phase is 0.7 or more in a total weight of the α crystal phase and a β crystal phase.

16. The electrostatic chuck heater of claim 11, wherein the silicon nitride sintered body has a thermal conductivity of 70 W/mK or more and a three-point bending strength of 650 MPa or more.

17. The electrostatic chuck heater of claim 11, wherein the silicon nitride powder is manufactured by processes comprising:
manufacturing a mixed raw material powder containing a metallic silicon powder, and α crystal phase control powder containing a rare earth element-containing compound and a magnesium-containing compound;
producing granules having a predetermined particle diameter by mixing the mixed raw material powder with a solvent and an organic binder to form a slurry and then spray drying;
nitriding the granules at a predetermined temperature within a range of 1200 to 1500° C. while applying nitrogen gas at a predetermined pressure, to obtain nitrided granules; and
pulverizing the nitrided granules.

18. The electrostatic chuck heater of claim 17, wherein the metallic silicon powder has an average particle diameter of 0.5 μm to 4 μm, rare earth element-containing compound powder has an average particle diameter of 0.1 μm to 1 μm, and magnesium-containing compound powder has an average particle diameter of 0.1 μm to 1 μm.

19. The electrostatic chuck heater of claim 17, wherein the granules have a D50 value of 20 μm to 55 μm.

20. The electrostatic chuck heater of claim 17,
wherein the rare earth element-containing compound is yttrium oxide, and the magnesium-containing compound is magnesium oxide, and
the mixed raw material powder contains 2 mol % to 5 mol % of yttrium oxide and 2 mol % to 10 mol % of magnesium oxide.
